(19) United States
(12) Patent Application Publication
(10) Pub. No.: US 2007/0138134 A1
(43) Pub. Date: Jun. 21, 2007

(54) ETCHING APPARATUS AND ETCHING METHOD

(76) Inventors: Chuan-Han Hsieh, Hsinchu City (TW); Yu-Ming Liu, Hsinchu County (TW); Chiu-Liang Li, Taichung County (TW); Hui-Chin Hsu, Hsinchu City (TW); Kuo-Chih Yeh, Hsinchu County (TW); Hung-Te Cheng, Hsinchu City (TW); Chien-En Hsu, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,164

(22) Filed: Dec. 19, 2005

(51) Int. Cl. C03C 25/68; H01L 21/302; H01L 21/461; H01L 21/306

(52) U.S. Cl. 216/58; 438/706; 156/345.33

(57) ABSTRACT

An etching apparatus is described, including an etching chamber, a gas pipe, a gas distribution plate and a heater. The gas pipe is disposed above the etching chamber for delivering a gas to the exterior surface of the etching chamber. The gas distribution plate is disposed at the outlet of the gas pipe, including a plate body and an inner collar-shaped part thereon facing the outlet of the gas pipe. The inner collar-shaped part and the portion of the plate body around the inner collar-shaped part each has multiple through holes therein. The heater is disposed around the space between the gas pipe and the etching chamber for heating the gas flowing out of the gas distribution plate.

### BACKGROUND OF THE INVENTION

1. Field of the Invention

The present invention relates to an etching equipment and an etching method. More particularly, the present invention relates to an etching apparatus with a higher uniformity in the temperature distribution of the etching chamber, and to an etching method using the same etching apparatus.

2. Description of the Related Art

In an IC-fabricating process, a metal pattern is often defined by etching a metal layer with a lithographically patterned photoresist layer thereon as a mask to transfer the photoresist pattern to the metal layer. Hence, the metal etching process plays a very important role in IC fabrication.

A metal etching process is usually conducted in a plasma etching apparatus, and a conventional plasma etching apparatus is depicted in FIG. 1. The etching apparatus 100 includes an etching chamber 103 that includes a chuck 104 for carrying and fixing a wafer 106 to be etched and a dome 102 disposed over the chuck 104. After the wafer 106 is placed on the chuck 104, an etching gas composition is introduced to the etching chamber 103 and made into plasma with RF power to etch the surface of the wafer 106.

The etching apparatus 100 also includes a temperature control system 105 over the etching chamber 103 for regulating the temperature of the upper portion of the latter to reduce the amount of the polymer adhering to the interior surface of the dome 102, wherein the polymer is formed from the gaseous etching by-products. A conventional temperature control system 105 includes a heater, a gas pipe and a gas nozzle, wherein the gas nozzle is illustrated in FIG. 2A/2B in a side/bottom view.

The gas nozzle 110 is disposed over the etching chamber 103 and connected to the gas pipe for introducing a gas of lower temperature into the etching apparatus 100. The introduced gas is adjusted in temperature by the heater and flowed onto the exterior surface of the dome 102 to control the temperature distribution of the same. However, because the bottom opening of the gas nozzle 110 is formed much wider than the top opening, the central part of the dome 102 directly under the gas nozzle 110 is subject to a stronger gas flow and tends to be colder than the other parts. Hence, the central part of the interior surface of the dome 102 is deposited with thicker polymer as compared with the other parts, so that the polymer easily peels off and drops to the surface of the wafer. As a result, the process reliability is lowered and the period of the prevention maintenance (PM) cycle is shortened, thus increasing the cost of the fabricating process.

Moreover, U.S. Pat. No. 6,822,185 discloses an inductively coupled plasma (ICP) system as a temperature-controlling coil system that uses one or more of various techniques to regulate the temperature of the etching chamber. However, the method either cannot effectively solve the above polymer issue.

### SUMMARY OF THE INVENTION

Accordingly, this invention provides an etching apparatus with higher uniformity in the temperature distribution of the etching chamber, so as to prevent a thickness non-uniformity of the polymer adhering to the interior surface of the etching chamber.

This invention also provides an etching method that utilizes the same etching apparatus of this invention.

The etching apparatus of this invention includes an etching chamber, a gas pipe over the etching chamber for delivering a gas to the exterior surface of the latter, a gas distribution plate at the outlet of the gas pipe, and a heater. The gas distribution plate includes a plate body and an inner collar-shaped part thereon facing the outlet of the gas pipe, wherein the inner collar-shaped part and the portion of the plate body around the inner collar-shaped part each has multiple through holes therein. The heater is disposed around the space between the gas pipe and the etching chamber for heating the gas flowing out of the gas distribution plate.

According to various embodiments of the etching apparatus, the gas distribution plate may further include an outer collar-shaped part that surrounds the plate body. The plate body of the gas distribution plate may be shaped as a round disk, and the inner collar-shaped part may be shaped as a round ring. The plate body and the inner collar-shaped part may be formed in an integral. The through holes may be distributed evenly on the inner collar-shaped part and the portion of the plate body around the inner collar-shaped part. The gas delivered by the gas pipe may be compressed dry air. The heater may include a heating lamp. The etching chamber may include a chuck and a dome disposed over the chuck, wherein the chuck is for carrying and fixing a wafer to be etched, and the material of the dome may be ceramic.

The etching method of this invention uses an etching apparatus of this invention and includes the following steps. A wafer to be etched is placed in the etching chamber. The wafer is then etched, and a gas is simultaneously delivered into the etching apparatus through the gas pipe and the gas distribution plate to blow the exterior surface of the etching chamber, while the heater is used to adjust the temperature of the gas flowing out of the gas distribution plate.

Because the portion of the plate body of the gas distribution plate corresponding to the outlet of the gas pipe has no through holes therein and the other portion of the plate body and the inner collar-shaped part each has multiple through holes therein, the introduced gas can be distributed more evenly than before. Thus, the central part of the exterior surface of the etching chamber does not tend to be colder than the other parts, so that the polymer adhering to the interior surface of the same is more uniform in the thickness and does not easily peel off to contaminate the wafer surface.

It is to be understood that both the foregoing general description and the following detailed description are exemplary, and are intended to provide further explanation of the invention as claimed.

### BRIEF DESCRIPTION OF THE DRAWINGS

FIG. 1 schematically illustrates a conventional plasma etching apparatus.

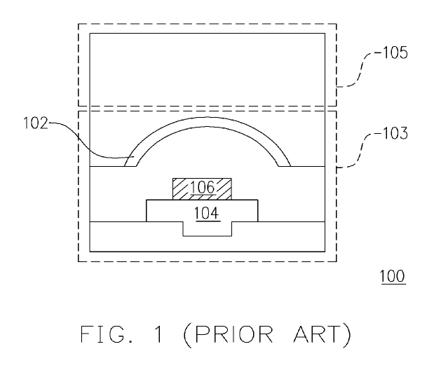

FIG. 2A/2B illustrates a side/bottom view of a gas nozzle used in the temperature control system of the conventional plasma etching apparatus.

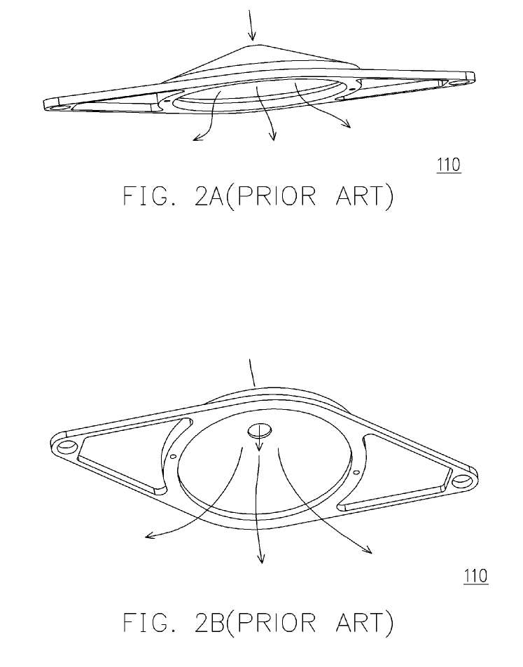

FIG. 3 schematically illustrates an etching apparatus according to an embodiment of this invention, and FIG. 4 illustrates a perspective view of a gas distribution plate used in the etching apparatus according to the embodiment of this invention.

### DESCRIPTION OF THE PREFERRED EMBODIMENTS

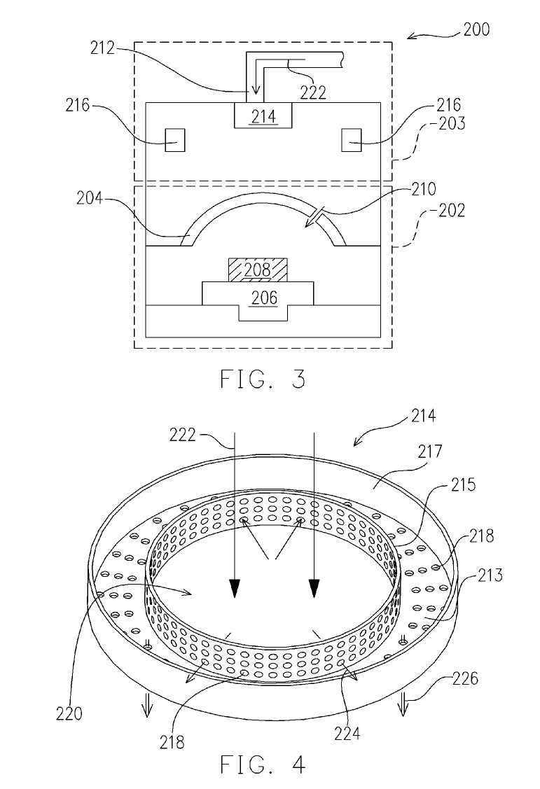

Referring to FIG. 3, the etching apparatus 200 includes an etching chamber 202 and a temperature control system 203. The etching chamber 202 usually includes a chuck 206 and a dome 204 disposed over the chuck 206, wherein the material of the dome 204 may be ceramic. The chuck 206 is for carrying and fixing a wafer 208 to be etched, and may be one capable of moving up and down such that the wafer 208 can be raised or lowered as required. The etching gas composition for generating the etching plasma may be introduced into the etching chamber 202 through a gas inlet 210 on the dome 204, and the electrodes for providing RF power to generate the etching plasma may be disposed in the etching chamber 202.

The temperature control system 203 includes a gas pipe 212, a gas distribution plate 214 and a heater 216 at least. The gas pipe 212 is disposed over the dome 204 for delivering a gas to the exterior surface of the latter, wherein the gas serves as a cooling source in the temperature control system 203 and may be compressed dry air or other gas that will not damage the inside of the etching apparatus 200. The heater 216 is disposed around the space between the gas pipe 212 and the etching chamber 202 for heating the gas flowing out of the gas distribution plate 214. In other words, the heater 216 serves as a heating source that counteracts with the gas as a cooling source to control the temperature distribution of the upper portion of the etching chamber 202. The heater 216 may be a heating lamp or another type of heater. Though only two heaters 216 are depicted in FIG. 3, the number of heaters can be increased or decreased as required and is not particularly limited in this invention.

Referring to FIGS. 3-4, the etching apparatus 200 features the gas distribution plate 214, which is disposed at the outlet of the gas pipe 212 so that the gas passing the gas pipe 212 can be evenly distributed to the exterior surface of the dome 204. The gas distribution plate 214 includes a plate body 213 and an inner collar-shaped part 215 thereon, wherein the inner collar-shaped part 215 faces the outlet of the gas pipe 212 and encloses on the plate body 213 an area 220 that substantially corresponds to the area of the outlet of the gas pipe 212. The inner collar-shaped part 215 and the portion of the plate body 213 around the inner collar-shaped part 215 each has may through holes 218 therein, which may be distributed evenly. In some embodiments, the plate body 213 may be shaped as a round disk, and the inner collar-shaped part 215 may be shaped as a round ring whose center position is the same as that of the round disk. When the etching apparatus 200 is designed for a wafer of eight inches, for example, the diameter of the plate body 213 of the gas distribution plate 214 may be six inches and that of the inner collar-shaped part 215 may be four inches. The gas distribution plate 214 may further include an outer collar-shaped part 217 that surrounds the plate body 213. The outer collar-shaped part 217 has no through therein, so that the gas hardly flows down from the edge of the plate body 213 and the gas flow distribution is controlled better.

This invention does not particularly limit the shapes of the plate body 213 and the inner/outer collar-shaped part 215/217 as well as the shape and the number of the through holes 218, while the shape of the plate body 213 can be modified to match that of the outlet of the gas pipe 212. In addition, the plate body 213 and the inner collar-shaped part 215 of the gas distribution plate 214 may be formed in an integral. Similarly, in a case where an outer collar-shaped part 217 is further included, the plate body 213, the inner and outer collar-shaped parts 215 and 217 may be formed in an integral. The function of the gas distribution plate 214 is explained as follows.

Referring to FIGS. 3-4 again, in the etching method, a wafer 208 to be etched is placed in the etching chamber 202 of the etching apparatus 200 and then etched. The wafer 208 may have been formed with a metal layer to be etched thereon. However, this invention is not restricted to apply to a metal-etching apparatus, but can also be applied to an apparatus for etching poly-Si or SiO or other dielectric material. That is, the wafer 208 may have been formed with a layer of poly-Si, SiO or other dielectric.

When the wafer 208 is being etched, a gas is continuously introduced into the etching apparatus 200 through the gas pipe 212 and the gas distribution plate 214 to evenly blow the exterior surface of the dome 204, while the heater 216 is used to adjust the temperature of the gas flowing out of the gas distribution plate 214.

Referring to FIG. 4, when the gas is introduced through the gas distribution plate 214, the gas flow passing the gas pipe 212 firstly passes the through holes 218 in the inner collar-shaped part 215 and then the through holes 218 in the plate body 213, as indicated by the arrows 222, 224 and 226. Thereby, the gas can be distributed evenly.

Moreover, in an etching experiment using the above etching apparatus, it was found that the thickness of the polymer on the interior surface of the dome was always uniform for a use period of 50 hours, 70 hours, 104 hours or 135 hours. Therefore, the period of the PM cycle can be increased to reduce the cost. Also, in an experiment where the etching apparatus was used to define metal lines of 0.14 μm, it was found that the critical dimension (CD) of the metal lines defined is 0.1397 μm, which is very close to that (0.1419 μm) obtained with a conventional etching apparatus. Accordingly, this invention does not adversely affect the accuracy of the pattern transfer.

Accordingly, this invention can make the temperature of the exterior surface of the dome more uniform, so that the polymer on the interior surface is more uniform in the thickness and does not easily peel off to contaminate the wafer surface.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A etching apparatus, comprising:
an etching chamber;
a gas pipe, disposed over the etching chamber for delivering a gas to an exterior surface of the etching chamber;
a gas distribution plate disposed at an outlet of the gas pipe, comprising a plate body and an inner collar-shaped part thereon facing the outlet of the gas pipe, wherein the inner collar-shaped part and a portion of the plate body around the inner collar-shaped part each has a plurality of through holes therein; and
a heater, disposed around a space between the gas pipe and the etching chamber for heating the gas flowing out of the gas distribution plate.

2. The etching apparatus of claim 1, wherein the gas distribution plate further comprises an outer collar-shaped part surrounding the plate body.

3. The etching apparatus of claim 1, wherein the plate body of the gas distribution plate is shaped as a round disk.

4. The etching apparatus of claim 1, wherein the inner collar-shaped part of the gas distribution plate is shaped as a round ring.

5. The etching apparatus of claim 1, wherein the plate body and the inner collar-shaped part of the gas distribution plate are formed in an integral.

6. The etching apparatus of claim 1, wherein the through holes are distributed evenly on the inner collar-shaped part and the portion of the plate body around the inner collar-shaped part.

7. The etching apparatus of claim 1, wherein the gas delivered by the gas pipe comprises compressed dry air.

8. The etching apparatus of claim 1, wherein the heater comprises a heating lamp.

9. The etching apparatus of claim 1, wherein the etching chamber comprises a chuck and a dome disposed over the chuck, wherein the chuck is for carrying and fixing a wafer to be etched.

10. The etching apparatus of claim 9, wherein the dome comprises ceramic.

11. An etching method that uses an etching apparatus comprising an etching chamber, a gas pipe over the etching chamber, a gas distribution plate at an outlet of the gas pipe and a heater around a space between the gas pipe and the etching chamber, wherein the gas distribution plate comprises a plate body and an inner collar-shaped part thereon facing the outlet of the gas pipe and the inner collar-shaped part and a portion of the plate body around the inner collar-shaped part each has a plurality of through holes therein, the etching method comprising:
placing a wafer to be etched in the etching chamber; and
etching the wafer, and simultaneously introducing a gas into the etching apparatus through the gas pipe and the gas distribution plate to blow an exterior surface of the etching chamber as well as using the heater to adjust temperature of the gas flowing out of the gas distribution plate.

12. The etching method of claim 11, wherein the gas distribution plate further comprises an outer collar-shaped part surrounding the plate body.

13. The etching method of claim 11, wherein the plate body of the gas distribution plate is shaped as a round disk.

14. The etching method of claim 11, wherein the inner collar-shaped part of the gas distribution plate is shaped as a round ring.

15. The etching method of claim 11, wherein the plate body and the inner collar-shaped part of the gas distribution plate are formed in an integral.

16. The etching method of claim 11, wherein the through holes are distributed evenly on the inner collar-shaped part and the portion of the plate body around the inner collar-shaped part.

17. The etching method of claim 11, wherein the gas delivered by the gas pipe comprises compressed dry air.

18. The etching method of claim 11, wherein the heater comprises a heating lamp.

19. The etching method of claim 11, wherein the etching chamber comprises a chuck and a dome disposed over the chuck, wherein the chuck is for carrying and fixing the wafer.

20. The etching method of claim 19, wherein the dome comprises ceramic.
